(19) United States
(12) Patent Application Publication
(10) Pub. No.: US 2025/0080103 A1
(43) Pub. Date: Mar. 6, 2025

(54) SEMICONDUCTOR DEVICE, AMPLIFIER AND BIASING CIRCUIT

(71) Applicant: Realtek Semiconductor Corporation, Hsinchu (TW)

(72) Inventor: Kai-Yen CHANG, Hsinchu (TW)

(21) Appl. No.: 18/817,222

(22) Filed: Aug. 28, 2024

Related U.S. Application Data
(60) Provisional application No. 63/580,388, filed on Sep. 4, 2023.

(30) Foreign Application Priority Data
Jun. 4, 2024 (TW) 113120691

(51) Int. Cl. H03K 17/082; H03F 1/52

(52) U.S. Cl. CPC H03K 17/0822; H03F 1/523

(57) ABSTRACT

A semiconductor device includes a first transistor, a second transistor and a third transistor. The first transistor is controlled by a first switch signal, and is configured to be conducted in a first enable period. The second transistor is controlled by a second switch signal, and are configured to conduct at least in a second enable period. The first enable period includes a first delay period, the second enable period and a second delay period arranged sequentially. The third transistor is controlled by a third switch signal, and is configured to be conducted at least in a third enable period. The second transistor is coupled between the first transistor and the third transistor. The second enable period includes a third delay period, the third enable period and a fourth delay period arranged sequentially.

### CROSS-REFERENCE TO RELATED APPLICATION

This application claims priority to U.S. Provisional Application Ser. No. 63/580,388 filed Sep. 4, 2023, and Taiwan Application Serial Number 113120691, filed Jun. 4, 2024, the disclosures of which are incorporated herein by reference in their entireties.

### BACKGROUND

### Field of Invention

The present disclosure is associated with semiconductor circuit technology that is particular about a semiconductor device, an amplifier, and a biasing circuit that can be prevented from surge or overshoot.

### Description of Related Art

As semiconductor process technology advances, transistor channel lengths and gate oxide thicknesses are shrinking. As a result, wafers made with advanced processes have the advantages of low power consumption, high component density, and high computing speed. However, the thinner oxide thickness means lower voltage tolerance, so transistors in the chip of input/output (I/O) circuits are often damaged by voltage or current surges.

### SUMMARY

The present disclosure provides a semiconductor device that includes a first transistor, a second transistor, and a third transistor. The first transistor is controlled by a first switch signal, which is configured to be conducted in a first enable period. The second transistor is controlled by a second switch signal, which is configured to be conducted at least in a second enable period. The first enable period includes a first delay period, the second enable period, and a second delay period that are arranged sequentially. The third transistor is controlled by a third switch signal, which is configured to be conducted at least in a third enable period. The second transistor is coupled between the first transistor and the third transistor. The second enable period includes a third delay period, the third enable period, and a fourth delay period that are arranged sequentially.

The present disclosure provides an amplifier that includes a first semiconductor device and a second semiconductor device. The second semiconductor device is coupled to the first semiconductor device. Each of the first semiconductor device and the second semiconductor device includes a first transistor, a second transistor, and a third transistor. The first transistor is controlled by a first switch signal, which is configured to be conducted in a first enable period. The second transistor is controlled by a second switch signal, which is configured to be conducted at least in a second enable period. The first enable period includes a first delay period, the second enable period, and a second delay period that are arranged sequentially. The third transistor is controlled by a third switch signal, which is configured to be conducted at least in a third enable period. The second transistor is coupled between the first transistor and the third transistor. The second enable period includes a third delay period, the third enable period, and a fourth delay period that are arranged sequentially. The first transistor is configured to receive an input signal, and the third transistor is configured to generate an output signal.

The present disclosure provides a biasing circuit that includes a semiconductor device, a first voltage generation circuit, a second voltage generation circuit, and a third voltage generation circuit. The semiconductor device includes a first transistor, a second transistor, and a third transistor. The second transistor is coupled between the first transistor and the third transistor. The first voltage generation circuit is configured to output a first switch signal to control the first transistor to be conducted in a first enable period. The second voltage generation circuit is configured to output a second switch signal to control the second transistor to be conducted at least in a second enable period. The first enable period includes a first delay period, the second enable period, and a second delay period that are arranged sequentially. Each of the second voltage generation circuit and its corresponding second transistor form a negative feedback. The third voltage generation circuit is configured to output a third switch signal to control the third transistor to be conducted at least in a third enable period. The second enable period includes a third delay period, the third enable period, and a fourth delay period that are arranged sequentially.

One of advantages of the semiconductor device, the amplifier, and the biasing circuit above is to prevent surge or overshoot.

### BRIEF DESCRIPTION OF THE DRAWINGS

FIG. 1A illustrates a diagram of a semiconductor device, in accordance with one embodiment of the present disclosure.

FIG. 1B illustrates a diagram of a semiconductor device, in accordance with the other embodiment of the present disclosure.

FIG. 2 illustrates a diagram of signal waveforms of the semiconductor device, in accordance with one embodiment of the present disclosure.

FIG. 3 illustrates a diagram of signal waveforms of the semiconductor device, in accordance with one embodiment of the present disclosure.

FIG. 4 illustrates a diagram of a semiconductor device, in accordance with one embodiment of the present disclosure.

FIG. 5 illustrates a diagram of signal waveforms of the semiconductor device, in accordance with one embodiment of the present disclosure.

FIG. 6 illustrates a diagram of an amplifier, in accordance with one embodiment of the present disclosure.

FIG. 7 illustrates a diagram of a biasing circuit, in accordance with one embodiment of the present disclosure.

### DETAILED DESCRIPTION

Embodiments of the present disclosure are described below in conjunction with related figures. In the figures, the same symbols indicate the same or similar components or method processes.

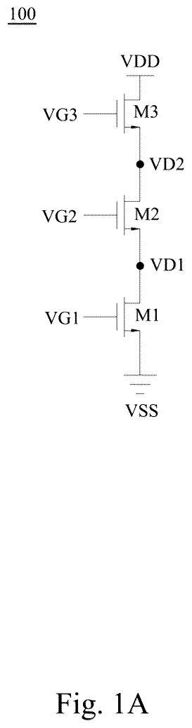

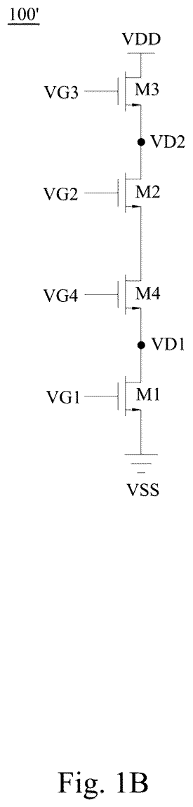

FIG. 1A illustrates a diagram of a semiconductor device 100, in accordance with one embodiment of the present disclosure. The semiconductor device 100 includes a first transistor M1, a second transistor M2, and a third transistor M3. The first transistor M1, the second transistor M2, and the third transistor M3 are coupled in series between a power terminal VSS and a power terminal VDD sequentially, in which a voltage of the power terminal VDD is higher than a voltage of the power terminal VSS. The first transistor M1, the second transistor M2, and the third transistor M3 are respectively controlled by a first switch signal VG1, a second switch signal VG2, and a third switch signal VG3. In some embodiments, the first transistor M1, the second transistor M2, and the third transistor M3 can be implemented by N-type metal-oxide-semiconductor field-effect transistors (NMOSFETs) (simply referred to as N-type transistors). In some embodiments of the semiconductor device 100 as an input/output (I/O) circuit, the semiconductor device 100 is a biasing circuit.

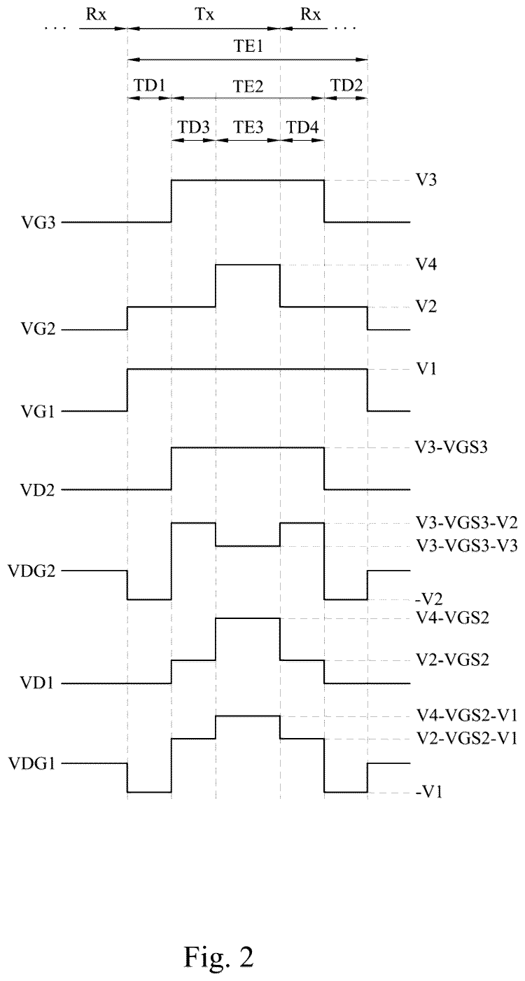

Reference is now made to both FIG. 1A and FIG. 2, in which FIG. 2 illustrates a diagram of signal waveforms of the semiconductor device 100, in accordance with one embodiment of the present disclosure. FIG. 2 illustrates the following timing relationships between multiple signals and multiple voltages: the first switch signal VG1, the second switch signal VG2, the third switch signal VG3, a drain voltage VD1 of the first transistor M1, a drain-gate voltage VDG1 of the first transistor M1, a drain voltage VD2 of the second transistor M2, a drain-gate voltage VDG2 of the second transistor M2, a gate-source voltage VGS2 of the second transistor M2, and a gate-source voltage VGS3 of the third transistor M3. The semiconductor device 100 can operate in a receiving mode Rx and a transmitting mode Tx alternately. Before switching from the receiving mode Rx to the transmitting mode Tx, the semiconductor device 100 doesn't output the signal, so the first switch signal VG1, the second switch signal VG2, and the third switch signal VG3 have low voltages (e.g., ground voltage) to switch off the first transistor M1, the second transistor M2, and the third transistor M3.

When entering the transmitting mode Tx, the first switch signal VG1 is switched to a first voltage V1 to conduct the first transistor M1, and the second switch signal VG2 is switched to a second voltage V2 to conduct the second transistor M2. Thus, a drain of the first transistor M1 and a drain of the second transistor M2 are in a low impedance state. The first switch signal VG1 maintains at the first voltage V1 in a first enable period TE1, in which the first enable period TE1 includes a first delay period TD1, a second enable period TE2, and a second delay period TD2 arranged sequentially. The second switch signal VG2 maintains at the second voltage V2 in the first delay period TD1. When entering the transmitting mode Tx and passing the first delay period TD1, the third switch signal VG3 is switched to a third voltage V3 to conduct the third transistor M3. The third switch signal VG3 maintains at the third voltage V3 in the second enable period TE2, in which the second enable period TE2 includes a third delay period TD3, a third enable period TE3, and a fourth delay period TD4 arranged sequentially.

In this way, even if the third transistor M3 is conducted early due to a shift in a device characteristic, there is no voltage surge or overshoot at the drains of the first transistor M1 and the second transistor M2 because the drains of the first transistor M1 and the second transistor M2 have already been placed in the low impedance state beforehand.

At the end of the first delay period TD1, the second switch signal VG2 keeps being at the second voltage V2 in the third delay period TD3. Then, the second switch signal VG2 is switched to a fourth voltage V4 and maintains at the fourth voltage V4 in the third enable period TE3, in which the fourth voltage V4 is higher than the second voltage V2 and higher than a breakdown voltage of the second transistor M2. At the end of the third enable period TE3, the second switch signal VG2 is switched to the second voltage V2 and maintains at the second voltage V2 during the following the fourth delay period TD4 and the second delay period TD2.

On the other hand, when the fourth delay period TD4 ends, the third switch signal VG3 is switched from the third voltage V3 to the low voltage to switch off the third transistor M3. In this way, even if the third transistor M3 is delayed to be switched off due to the shift in the device characteristic, there is no voltage surge or overshoot at the drains of the first transistor M1 and the second transistor M2 because the drains of the first transistor M1 and the second transistor M2 are still in the low impedance state.

The first delay period TD1 and the second delay period TD2 can be the same or different. The third delay period TD3 and the fourth delay period TD4 can be the same or different. In some embodiments, the first delay period TD1, the second delay period TD2, the third delay period TD3, and the fourth delay period TD4 are respectively in the range of 50-200 nanoseconds (ns), but the present disclosure is not limited to them. In some embodiments, a sum of the first delay period TD1 and the third delay period TD3 is longer to wait for a low-dropout regulator (LDO regulator) that provides power for the first power terminal VDD to enter a steady state, and a sum of the second delay period TD2 and the fourth delay period TD4 is shorter to stop an output of the semiconductor device 100 as soon as possible.

In summary, to prevent the semiconductor device 100 from being damaged by the voltage surge or overshoot, the first transistor M1 is configured to be conducted in the first enable period TE1, the second transistor M2 is configured to be conducted at least in the second enable period TE2, and the third transistor M3 is configured to be conducted at least in the third enable period TE3. The first enable period TE1 includes the first delay period TD1, the second enable period TE2, and the second delay period TD2 arranged sequentially. The second enable period TE2 includes the third delay period TD3, the third enable period TE3, and the fourth delay period TD4 arranged sequentially.

It is noteworthy that the fourth voltage V4 is higher than the second voltage V2, so an on-state resistance of the second transistor M2 in the third enable period TE3 is lower than on-state resistances of the second transistor M2 in the first delay period TD1, the second delay period TD2, the third delay period TD3, and the fourth delay period TD4.

In some embodiments, the first voltage V1 is lower than a breakdown voltage of the first transistor M1 and higher than a threshold voltage of the first transistor M1, so an absolute value of the drain-gate voltage VDG1 of the first transistor M1 keeps lower than an absolute value of the breakdown voltage of the first transistor M1.

In the other embodiments, the second voltage V2 is lower than a breakdown voltage of the second transistor M2 and higher than a threshold voltage of the second transistor M2. In the first delay period TD1, the second delay period TD2, the third delay period TD3, and the fourth delay period TD4, a voltage (i.e., the second voltage V2) of the second switch signal VG2 is between the threshold voltage of the second transistor M2 and the breakdown voltage of the second transistor M2. In the third enable period TE3, the breakdown voltage of the second transistor M2 is between the threshold voltage of the second transistor M2 and a voltage (i.e., the fourth voltage V4) of the second switch signal VG2. Thus, an absolute value of the drain-gate voltage VDG2 of the second transistor M2 keeps lower than an absolute value of the breakdown voltage of the second transistor M2.

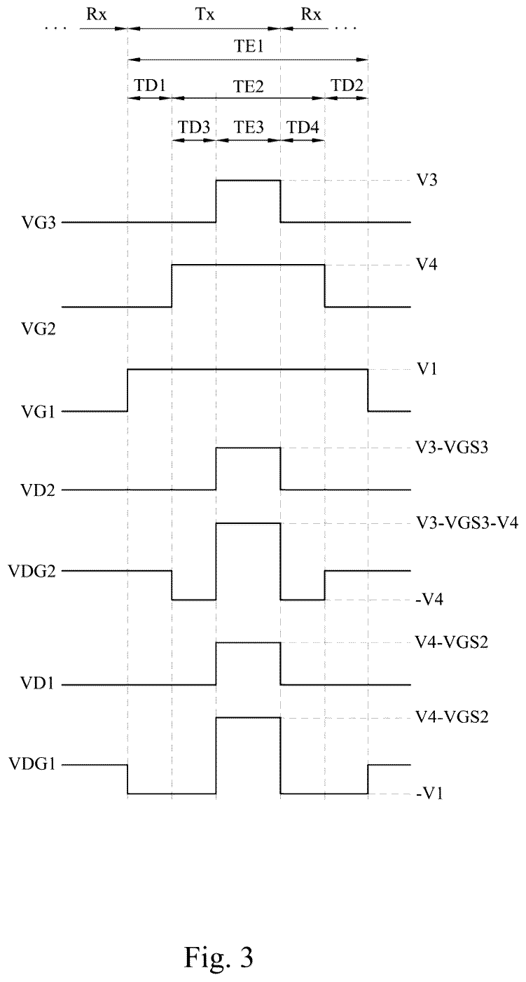

FIG. 3 illustrates a diagram of signal waveforms of the semiconductor device 100, in accordance with one embodiment of the present disclosure. The embodiment in FIG. 3 is similar to the embodiment in FIG. 2, so the following only explains the differences between the two. In the embodiment in FIG. 3, the second switch signal VG2 has the low voltages in the first delay period TD1 and the second delay period TD2 and maintains at the fourth voltage V4 in the second enable period TE2. The third switch signal VG3 in the first delay period TD1, the second delay period TD2, the third delay period TD3, and the fourth delay period TD4 have the low voltages, and the third switch signal VG3 has the third voltage V3 in the third enable period TE3.

Based on the above, the second switch signal VG2 and the third switch signal VG3 can have simpler waveforms or shorter pulse widths. As long as the second transistor M2 is conducted at least in the second enable period TE2 and the third transistor M3 is conducted at least in the third enable period TE3, an advantage of preventing surge or overshoot can be implemented.

Additionally, FIG. 1A described above illustrates the second transistor M2 between the first transistor M1 and the third transistor M3, but the present disclosure is not limited to them.

In the other embodiment, multiple transistors can be arranged in series between the first transistor M1 and the third transistor M3. Also referring to FIG. 1B, it illustrates a diagram of a semiconductor device 100′ of the other embodiment of the present disclosure. In the embodiment shown as FIG. 1B, the semiconductor device 100′ configures the second transistor M2 and the fourth transistor M4 between the third transistor M3 and the first transistor M1. The second transistor M2 and the fourth transistor M4 are coupled in series to the third transistor M3 and the first transistor M1, and the second transistor M2 and the fourth transistor M4 are respectively controlled by the second switch signal VG2 and a fourth switch signal VG4. In one embodiment, a signal waveform of the fourth switch signal VG4 is similar to the signal waveform of the second switch signal VG2 in FIG. 2 or FIG. 3, so the second transistor M2 and the fourth transistor M4 have a same or similar operation. For the sake of brevity, the part of the description will not be repeated. And so on, two or more than two transistors that couple each other in series can be arranged between the third transistor M3 and the first transistor M1. Multiple transistors that couple each other in series (e.g., the second transistor M2 and the fourth transistor M4 shown as FIG. 1B) can be controlled by the similar switch signals, which can achieve the functions and the operations described above by FIG. 1A, FIG. 2, and FIG. 3. In some embodiments, the third transistor M3 is implemented by an input/output device metal oxide semiconductor (IO MOS) or a laterally diffused metal oxide semiconductor (LDMOS). Thus, a breakdown voltage of the third transistor M3 is higher than the breakdown voltage of the first transistor M1 and higher than the breakdown voltage of the second transistor M2.

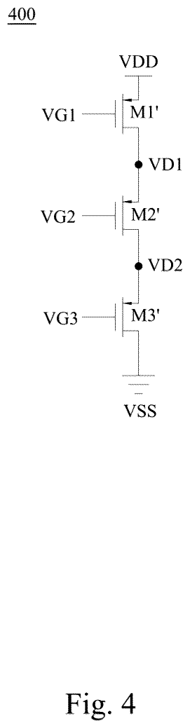

FIG. 4 illustrates a diagram of a semiconductor device 400, in accordance with one embodiment of the present disclosure. The semiconductor device 400 in FIG. 4 is similar to the semiconductor device 100 in FIG. 1A, so the following only explains the differences between the two. The semiconductor device 400 includes a first transistor M1′, a second transistor M2′, and a third transistor M3′, in which the first transistor M1′, the second transistor M2′, and the third transistor M3′ are coupled in series between the power terminal VDD and the power terminal VSS sequentially. In some embodiments, the first transistor M1′, the second transistor M2′, and the third transistor M3′ can be implemented by P-type transistors.

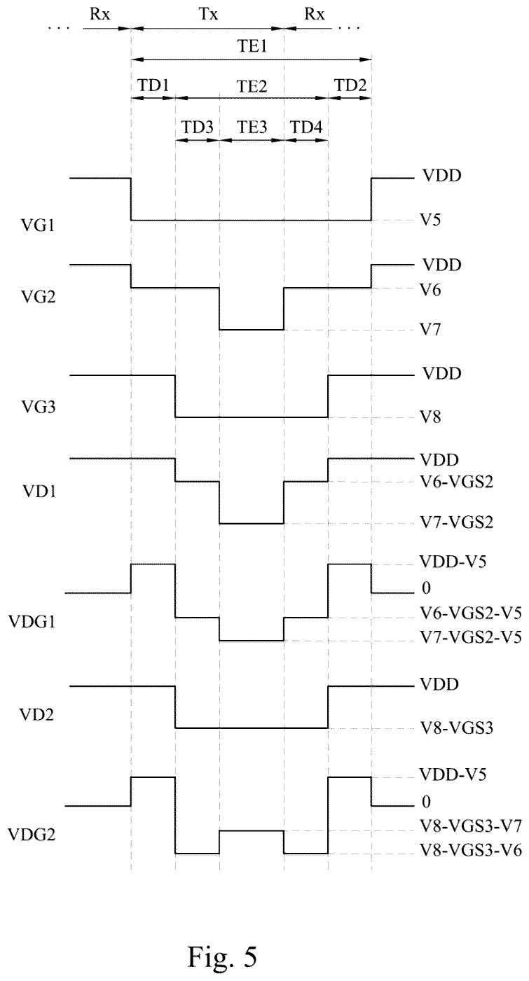

Reference is now made to both FIG. 4 and FIG. 5, in which FIG. 5 illustrates a diagram of signal waveforms of the semiconductor device 400, in accordance with one embodiment of the present disclosure. The signal timings in FIG. 5 are similar to those described in FIG. 2, but the signal waveforms are reversed. When entering the transmitting mode Tx, the first switch signal VG1 drops to a fifth voltage V5 to conduct the first transistor M1′. The first switch signal VG1 also maintains at the fifth voltage V5 in the first enable period TE1, which makes an absolute value of a gate-source voltage VGS1 (not shown in the figures) of the first transistor M1′ is higher than an absolute value of a threshold voltage V_{TH1} (not shown in the figures) of the first transistor M1′. That is, |VGS1|=|V5−VDD|>|V_{TH1}|, which makes the first transistor M1′ be conducted. The second switch signal VG2 has a sixth voltage V6 in the first delay period TD1, the second delay period TD2, the third delay period TD3, and the fourth delay period TD4 to conduct the second transistor M2′, which makes an absolute value of a gate-source voltage VGS2 (not shown in the figures) of the second transistor M2′ is higher than an absolute value of a threshold voltage V_{TH2} (not shown in the figures) of the second transistor M2′. That is, |VGS2|>|V_{TH2}|, which makes the second transistor M2′ be conducted. The second switch signal VG2 also has a seventh voltage V7 in the third enable period TE3, and the seventh voltage V7 is an actual voltage during the operation, which makes an absolute value of the drain-gate voltage VDG2 of the second transistor M2′ is lower than an absolute value of a breakdown voltage V_{BD2} (not shown in the figures) of the second transistor M2′, which is |VDG2|<|V_{BD2}|. The third switch signal VG3 has a high voltage in the first delay period TD1 and the second delay period TD2 (e.g., the voltage of the power terminal VDD), which makes the third transistor M3′ be switched off for preventing the first transistor M1′ and the second transistor M2′ from overshoot when switching switches. Additionally, in the second enable period TE2, the third switch signal VG3 drops to an eighth voltage V8 to conduct the third transistor M3′, which makes the biasing circuit (i.e., the semiconductor device 400) operate normally.

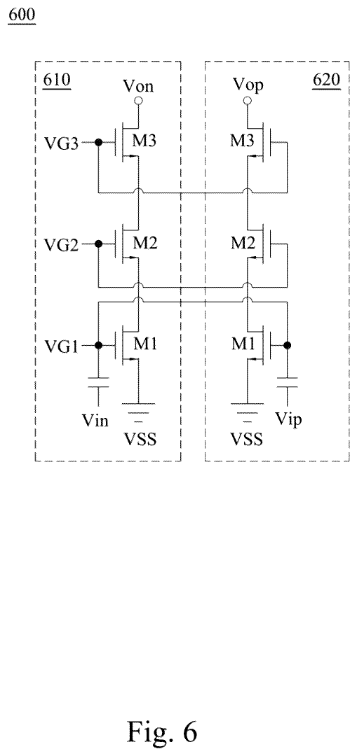

FIG. 6 illustrates a diagram of an amplifier 600, in accordance with one embodiment of the present disclosure. The amplifier 600 includes a first semiconductor device 610 and a second semiconductor device 620. The first semiconductor device 610 and the second semiconductor device 620 can be implemented respectively by the semiconductor device 100 in FIG. 1A, that is, the first semiconductor device 610 and the second semiconductor device 620 respectively have the first transistor M1, the second transistor M2, and the third transistor M3, in which the second transistor M2 is coupled to the first transistor M1 and the third transistor M3.

In the embodiment in FIG. 6, the first semiconductor device 610 and the second semiconductor device 620 respectively arrange one second transistor M2 between the third transistor M3 and the first transistor M1, but the present disclosure is not limited to them. In the other embodiment, the first semiconductor device 610 and the second semiconductor device 620 respectively arrange the multiple transistors in series between the third transistor M3 and the first transistor M1 (e.g., the second transistor M2 and the fourth transistor M4 shown as FIG. 1B). The above multiple series-connected transistors can be controlled by the same or similar switch signals, so the multiple series-connected transistors have the same or similar operation.

The first semiconductor device 610 and the second semiconductor device 620 are coupled to each other to receive the same first switch signal VG1, second switch signal VG2, and third switch signal VG3.

A gate of the first transistor M1 of the first semiconductor device 610 is configured to receive a first differential input signal Vin (e.g., an inverted differential input signal), and a drain of the second transistor M2 of the first semiconductor device 610 is configured to generate a first differential output signal Von (e.g., an inverted differential output signal). A gate of the first transistor M1 of the second semiconductor device 620 is configured to receive a second differential input signal Vip (e.g., a non-inverted differential input signal), and a drain of the second transistor M2 of the second semiconductor device 620 is configured to generate a second differential output signal Vop (e.g., a non-inverted differential output signal).

In operation, the first semiconductor device 610 and the second semiconductor device 620 are applicable to the signal waveforms of any of the multiple embodiments in FIG. 2 to FIG. 3 above. Thus, for each of the first semiconductor device 610 and the second semiconductor device 620, the first transistor M1 is configured to be conducted in the first enable period TE1, the second transistor M2 is configured to be conducted at least in the second enable period TE2, and the third transistor M3 is configured to be conducted at least in the third enable period TE3. The first enable period TE1 includes the first delay period TD1, the second enable period TE2, and the second delay period TD2 arranged sequentially. The second enable period TE2 includes the third delay period TD3, the third enable period TE3, and the fourth delay period TD4 arranged sequentially.

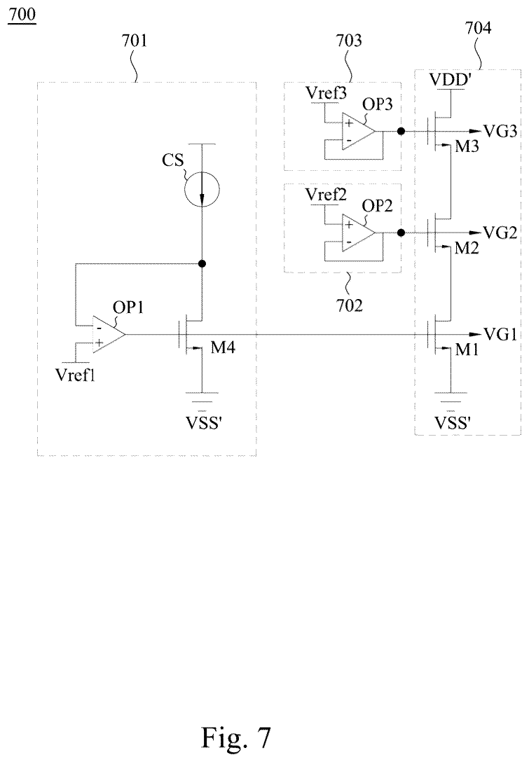

FIG. 7 illustrates a diagram of a biasing circuit 700, in accordance with one embodiment of the present disclosure. The biasing circuit 700 includes first voltage generation circuit 701, a second voltage generation circuit 702, a third voltage generation circuit 703, and a semiconductor device 704. The semiconductor device 704 can be implemented by the semiconductor device 100 in FIG. 1A, that is, the semiconductor device 704 include the first transistor M1, the second transistor M2, and the third transistor M3, and the first transistor M1, the second transistor M2, and the third transistor M3 are coupled between a power terminal VSS′ and a power terminal VDD′ sequentially.

In some embodiments, the biasing circuit 700 is coupled to the amplifier 600 in FIG. 6, and the biasing circuit 700 is configured to provide the first switch signal VG1, the second switch signal VG2, and the third switch signal VG3 to the amplifier 600 in FIG. 6. In one embodiment, an external computational circuit (not shown) can control voltages of a first reference voltage Vref1, a second reference voltage Vref2, and a third reference voltage Vref3, which makes the first switch signal VG1, the second switch signal VG2, and the third switch signal VG3 generated by the biasing circuit 700 have the signal waveforms of any of the embodiments in FIG. 2 to FIG. 3 above.

The first voltage generation circuit 701 includes a first amplifier OP1, a current source CS, and the fourth transistor M4. An inverted input terminal of the first amplifier OP1 is coupled to the current source CS and a drain of the fourth transistor M4 to form a negative feedback. A non-inverted input terminal of the amplifier OP1 is configured to receive the first reference voltage Vref1. An output terminal of the amplifier OP1 is configured to output the first switch signal VG1 to a gate of the first transistor M1 and a gate of the fourth transistor M4 of the semiconductor device 704 to control the first transistor M1 of the semiconductor device 704 to be conducted in the first enable period TE1.

The second voltage generation circuit 702 includes s second amplifier OP2. An inverted input terminal of the second amplifier OP2 is coupled to a source of its corresponding second transistor M2 to form the negative feedback, and an output terminal of the second amplifier OP2 is configured to output the second switch signal VG2 to its corresponding second transistor M2. Additionally, a non-inverted input terminal of the second amplifier OP2 is configured to receive the first reference voltage Vref1. An output terminal of the second amplifier OP2 is configured to output the second switch signal VG2 to a gate of the second transistor M2 of the semiconductor device 704 to control the second transistor M2 of the semiconductor device 704 to be conducted at least in the second enable period TE2.

In the embodiment in FIG. 7, the semiconductor device 704 includes the second transistor M2 arranged between the third transistor M3 and the first transistor M1, but the present disclosure is not limited to them. In the other embodiment, the semiconductor device 704 arranges the multiple series-connected transistors between the third transistor M3 and the first transistor M1 (e.g., the second transistor M2 and the fourth transistor M4 shown as FIG. 1B). The above multiple series-connected transistors can be controlled by the same or similar switch signals, so the multiple series-connected transistors have the same or similar operation.

The third voltage generation circuit 703 includes a third amplifier OP3. An inverted input terminal and an output terminal of the amplifier OP3 is coupled to each other to form the negative feedback, and the output terminal of the third amplifier OP3 is configured to output the third switch signal VG3. Additionally, a non-inverted input terminal of the third amplifier OP3 is configured to receive the second reference voltage Vref2. The output terminal of the third amplifier OP3 is configured to output the third switch signal VG3 to a gate of the third transistor M3 of the semiconductor device 704 to control the third transistor M3 of the semiconductor device 704 to be conducted at least in the third enable period TE3.

Certain terms are used in the specification and in the claims to refer to specific components. However, people having ordinary skill in the art can understand that the same component may be referred to by different terms. The specification and the claims do not distinguish components by differences in name, but rather by differences in function. The term “include” in the specification and the claims is an open-ended term and should be interpreted as “include but not limited to”. In addition, “couple” herein includes any direct and indirect means of connection. Thus, if a first element is described as being coupled to a second element, it means that the first element may be directly coupled to the second element through an electrical connection or a signal connection such as wireless transmission or optical transmission, or be indirectly coupled to the second element through the electrical connection or a signal connection by some other elements or means of connection.

Additionally, unless otherwise specified in this specification, any term used in the singular shall also include the plural.

The foregoing is only examples of the better embodiments of the present disclosure, and various modifications and equalization changes may be made to the present disclosure without departing from the scope or spirit of the present disclosure. In summary, all modifications and equalization changes to the present disclosure within the scope of the following claims are covered by the present disclosure.

What is claimed is:

1. A semiconductor device, comprising:
a first transistor controlled by a first switch signal and configured to be conducted in a first enable period;
a second transistor controlled by a second switch signal and configured to be conducted at least in a second enable period, wherein the first enable period comprises a first delay period, the second enable period, and a second delay period that are arranged sequentially; and
a third transistor controlled by a third switch signal and configured to be conducted at least in a third enable period, wherein the second transistor is coupled between the first transistor and the third transistor, and the second enable period comprises a third delay period, the third enable period, and a fourth delay period that are arranged sequentially.

2. The semiconductor device of claim 1, wherein the second transistor keeps conducted in the first enable period, and the third transistor keeps conducted in the second enable period.

3. The semiconductor device of claim 2, wherein the second transistor has an on-state resistance, and the on-state resistance in the third enable period is lower than the on-state resistance in the first delay period, the on-state resistance in the second delay period, the on-state resistance in the third delay period, and the on-state resistance in the fourth delay period.

4. The semiconductor device of claim 2, wherein the second transistor has a threshold voltage and a breakdown voltage,
wherein a voltage of the second switch signal is between the threshold voltage and the breakdown voltage in the first delay period, the second delay period, the third delay period, and the fourth delay period,
wherein the breakdown voltage is between the voltage of the second switch signal and the threshold voltage in the third enable period.

5. The semiconductor device of claim 1, wherein the second transistor is conducted in the second enable period and switched off in the first delay period and the second delay period,
wherein the third transistor is conducted in the third enable period and switched off in the first delay period, the second delay period, the third delay period, and the fourth delay period.

6. The semiconductor device of claim 1, wherein a breakdown voltage of the third transistor is higher than a breakdown voltage of the first transistor and higher than a breakdown voltage of the second transistor.

7. The semiconductor device of claim 1, further comprising:
a fourth transistor, wherein the second transistor and the fourth transistor are coupled in series between the third transistor and the first transistor.

8. The semiconductor device of claim 1, wherein the first transistor, the second transistor, and the third transistor are all P-type transistors or all N-type transistors.

9. An amplifier, comprising:
a first semiconductor device; and
a second semiconductor device coupled to the first semiconductor device, wherein each of the first semiconductor device and the second semiconductor device comprises:
a first transistor controlled by a first switch signal and configured to be conducted in a first enable period;
a second transistor controlled by a second switch signal and configured to be conducted at least in a second enable period, wherein the first enable period comprises a first delay period, the second enable period, and a second delay period that are arranged sequentially; and
a third transistor controlled by a third switch signal and configured to be conducted at least in a third enable period, wherein the second transistor is coupled between the first transistor and the third transistor, and the second enable period comprises a third delay period, the third enable period, and a fourth delay period that are arranged sequentially,
wherein the first transistor is configured to receive an input signal, and the third transistor is configured to generate an output signal.

10. The amplifier of claim 9, wherein the second transistor keeps conducted in the first enable period, and the third transistor keeps conducted in the second enable period.

11. The amplifier of claim 10, wherein the second transistor has an on-state resistance, and the on-state resistance in the third enable period is lower than the on-state resistance in the first delay period, the on-state resistance in the second delay period, the on-state resistance in the third delay period, and the on-state resistance in the fourth delay period.

12. The amplifier of claim 10, wherein the second transistor has a threshold voltage and a breakdown voltage,
wherein a voltage of the second switch signal is between the threshold voltage and the breakdown voltage in the first delay period, the second delay period, the third delay period, and the fourth delay period,
wherein the breakdown voltage is between the voltage of the second switch signal and the threshold voltage in the third enable period.

13. The amplifier of claim 9, wherein the second transistor is conducted in the second enable period and switched off in the first delay period and the second delay period,
wherein the third transistor is conducted in the third enable period and switched off in the first delay period, the second delay period, the third delay period, and the fourth delay period.

14. The amplifier of claim 9, wherein a breakdown voltage of the third transistor is higher than a breakdown voltage of the first transistor and higher than a breakdown voltage of the second transistor.

15. A biasing circuit, comprising:
a semiconductor device comprising a first transistor, a second transistor, and a third transistor, wherein the second transistor is coupled between the first transistor and the third transistor;
a first voltage generation circuit configured to output a first switch signal to control the first transistor to be conducted in a first enable period;
a second voltage generation circuit configured to output a second switch signal to control the second transistor to be conducted at least in a second enable period, wherein the first enable period comprises a first delay period, the second enable period, and a second delay period that are arranged sequentially, wherein the second voltage generation circuit and the second transistor form a negative feedback; and
a third voltage generation circuit configured to output a third switch signal to control the third transistor to be conducted at least in a third enable period, wherein the second enable period comprises a third delay period, the third enable period, and a fourth delay period that are arranged sequentially.

16. The biasing circuit of claim 15, wherein the second transistor keeps conducted in the first enable period, and the third transistor keeps conducted in the second enable period.

17. The biasing circuit of claim 16, wherein the second transistor has an on-state resistance, and the on-state resistance in the third enable period is lower than the on-state resistance in the first delay period, the on-state resistance in the second delay period, the on-state resistance in the third delay period, and the on-state resistance in the fourth delay period.

18. The biasing circuit of claim 16, wherein the second transistor has a threshold voltage and a breakdown voltage,
wherein a voltage of the second switch signal is between the threshold voltage and the breakdown voltage in the first delay period, the second delay period, the third delay period, and the fourth delay period,
wherein the breakdown voltage is between the voltage of the second switch signal and the threshold voltage in the third enable period.

19. The biasing circuit of claim 15, wherein the second transistor is conducted in the second enable period and switched off in the first delay period and the second delay period,
wherein the third transistor is conducted in the third enable period and switched off in the first delay period, the second delay period, the third delay period, and the fourth delay period.

20. The biasing circuit of claim 15, wherein a breakdown voltage of the third transistor is higher than a breakdown voltage of the first transistor and higher than a breakdown voltage of the second transistor.
